(19) United States
(12) Patent Application Publication
(10) Pub. No.: US 2025/0142905 A1
(43) Pub. Date: May 1, 2025

(54) SEMICONDUCTOR DEVICE

(71) Applicant: Samsung Electronics Co., Ltd., Suwon-si (KR)

(72) Inventors: Duckseoung KANG, Suwon-si (KR); Sangdeok KWON, Suwon-si (KR); Gibum KIM, Suwon-si (KR)

(73) Assignee: Samsung Electronics Co., Ltd., Suwon-si (KR)

(21) Appl. No.: 18/653,475

(22) Filed: May 2, 2024

(30) Foreign Application Priority Data
Oct. 31, 2023 (KR) 10-2023-0147917

(51) Int. Cl. H01L 29/08; H01L 29/06; H01L 29/417; H01L 29/423; H01L 29/775; H01L 29/786

(52) U.S. Cl. CPC H10D 62/151; H10D 30/43; H10D 30/6729; H10D 30/6735; H10D 30/6757; H10D 62/121

(57) ABSTRACT

A semiconductor device may include first, second, and third source/drain patterns, semiconductor patterns between the first and third source/drain patterns, a gate dielectric layer in contact with the semiconductor patterns, a gate electrode in contact with the gate dielectric layer, blocking semiconductor patterns between the first and second source/drain patterns, a blocking dielectric layer in contact with the blocking semiconductor patterns, and a blocking electrode in contact with the blocking dielectric layer. The blocking dielectric layer may include a first layer in contact with the first and second source/drain patterns, a second layer in contact with the blocking electrode, and a third layer between the first and second layers. A dielectric material of the third layer may be different than a dielectric material of the first layer and that of the second layer.

### CROSS-REFERENCE TO RELATED APPLICATION

This U.S. nonprovisional application claims priority under 35 U.S.C § 119 to Korean Patent Application No. 10-2023-0147917, filed on Oct. 31, 2023 in the Korean Intellectual Property Office, the disclosure of which is hereby incorporated by reference in its entirety.

### BACKGROUND

Inventive concepts relate to a semiconductor device, and more particular, to a semiconductor device including an active pattern.

A semiconductor device may include an integrated circuit with metal oxide semiconductor field effect transistors (MOSFETs). As a size and a design rule of the semiconductor device are gradually decreased, sizes of the MOSFETs are also increasingly scaled down. The scale down of MOSFETs may deteriorate operating characteristics of the semiconductor device. Accordingly, research has been variously developed to manufacture the semiconductor device having excellent performances while overcoming limitations due to integration of the semiconductor device.

### SUMMARY

Some embodiments of inventive concepts provide a semiconductor device with increased reliability and improved electrical properties and a method of fabricating the same.

According to an embodiment of inventive concepts, a semiconductor device may include a first source/drain pattern; a second source/drain pattern and a third source/drain pattern adjacent to the first source/drain pattern; a plurality of semiconductor patterns between the first source/drain pattern and the third source/drain pattern; a gate dielectric layer in contact with the plurality of semiconductor patterns; a gate electrode in contact with the gate dielectric layer; a plurality of blocking semiconductor patterns between the first source/drain pattern and the second source/drain pattern; a blocking dielectric layer in contact with the plurality of blocking semiconductor patterns; and a blocking electrode in contact with the blocking dielectric layer. The blocking dielectric layer may include a first layer in contact with the first source/drain pattern and the second source/drain pattern, a second layer in contact with the blocking electrode, and a third layer between the first layer and the second layer. A dielectric material in the third layer may be different from a dielectric material of the first layer and a dielectric material of the second layer.

According to an embodiment of inventive concepts, a semiconductor device may include a first source/drain pattern; a second source/drain pattern and a third source/drain pattern adjacent to the first source/drain pattern; a plurality of semiconductor patterns between the first source/drain pattern and the third source/drain pattern; a gate dielectric layer in contact with the plurality of semiconductor patterns; a gate electrode in contact with the gate dielectric layer; a plurality of blocking semiconductor patterns between the first source/drain pattern and the second source/drain pattern; a blocking dielectric layer in contact with the plurality of blocking semiconductor patterns; and a first blocking electrode in contact with the blocking dielectric layer. A dielectric material in the blocking dielectric layer may be different from a dielectric material of the gate dielectric layer.

According to an embodiment of inventive concepts, a semiconductor device may include a first source/drain pattern; a second source/drain pattern and a third source/drain pattern adjacent to the first source/drain pattern; a plurality of semiconductor patterns between the first source/drain pattern and the third source/drain pattern; a gate dielectric layer in contact with the plurality of semiconductor patterns; a gate electrode in contact with the gate dielectric layer; a gate electrode contact electrically connected to the gate electrode; a plurality of blocking semiconductor patterns between the first source/drain pattern and the second source/drain pattern; a blocking dielectric layer in contact with the blocking semiconductor patterns; a blocking electrode in contact with the blocking dielectric layer; a blocking electrode contact electrically connected to the blocking electrode; a plurality of gate spacers in contact with the blocking dielectric layer; a gate capping pattern in contact with the blocking dielectric layer and a top surface of the blocking electrode; and an active contact electrically connected to a corresponding one of the first source/drain pattern, the second source/drain pattern, and the third source/drain pattern. The blocking dielectric layer may include a first layer, a second layer, and a third layer. The first layer may be in contact with the first source/drain pattern, the second source/drain pattern, and the plurality of blocking semiconductor patterns. The second layer may be in contact with the blocking electrode. The third layer may be between the first layer and the second layer. The first layer and the second layer may include oxide. The third layer may include nitride.

### BRIEF DESCRIPTION OF DRAWINGS

FIGS. 1 and 2 illustrate conceptual diagrams showing logic cells of a semiconductor device according to some embodiments.

FIG. 3A illustrates a plan view showing a semiconductor device according to some embodiments.

FIG. 3B illustrates a cross-sectional view taken along line A-A′ of FIG. 3A.

FIG. 3C illustrates a cross-sectional view taken along line B-B′ of FIG. 3A.

FIG. 3D illustrates an enlarged view showing section E1 of FIG. 3B.

FIG. 3E illustrates an enlarged view showing section E2 of FIG. 3C.

FIGS. 4, 5, 6, 7, and 8 illustrate cross-sectional views showing a method of fabricating a semiconductor device depicted in FIGS. 3A to 3E.

FIG. 9 illustrates a cross-sectional view showing a semiconductor device according to some embodiments.

### DETAILED DESCRIPTION OF EMBODIMENTS

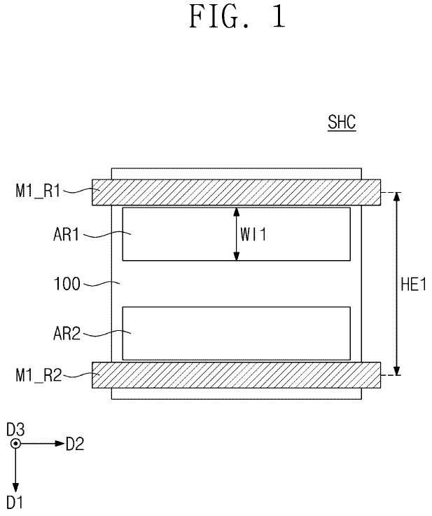

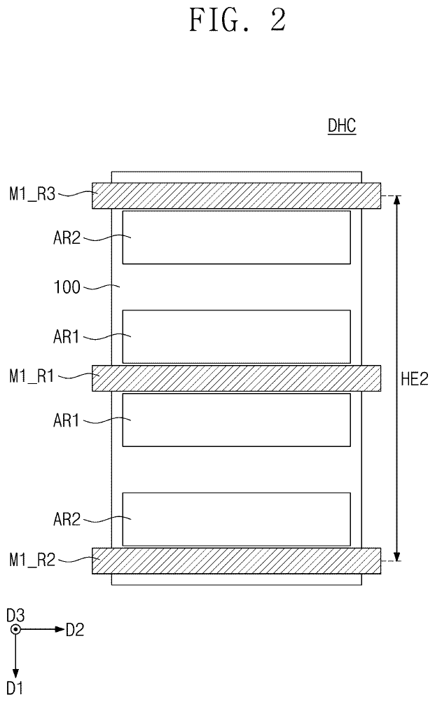

FIGS. 1 and 2 illustrate conceptual diagrams showing logic cells of a semiconductor device according to some embodiments.

Referring to FIG. 1, a single height cell SHC may be provided. For example, a substrate 100 may be provided thereon with a first power line M1_R1 and a second power line M1_R2. The first power line M1_R1 may be a path for providing a source voltage (VSS). For example, the first power line M1_R1 may be a path for providing a ground voltage. The second power line M1_R2 may be a path for providing a drain voltage (VDD). For example, the second power line M1_R2 may be a path for providing a power voltage.

The single height cell SHC may be defined between the first power line M1_R1 and the second power line M1_R2. The single height cell SHC may include one first active region AR1 and one second active region AR2. One of the first and second active regions AR1 and AR2 may be a PMOSFET region, and the other of the first and second active regions AR1 and AR2 may be an NMOSFET region. The single height cell SHC may have a complementary metal oxide semiconductor (CMOS) structure provided between the first power line M1_R1 and the second power line M1_R2.

Each of the first and second active regions AR1 and AR2 may have a first width WI1 in a first direction D1. A first height HE1 may be defined as a length in the first direction D1 of the single height cell SHC. The first height HE1 may be the same or substantially the same as a distance (e.g., pitch) between the first power line M1_R1 and the second power line M1_R2.

The single height cell SHC may constitute one logic cell. In this description, the logic cell may mean a logic device, such as AND, OR, XOR, XNOR, and inverter, that performs a specific function. The logic cell may include transistors for constituting a logic device and wiring lines for connecting the transistors to each other.

Referring to FIG. 2, a double height cell DHC may be provided. For example, a substrate 100 may be provided thereon with a first power line M1_R1, a second power line M1_R2, and a third power line M1_R3. The first power line M1_R1 may be disposed between the second power line M1_R2 and the third power line M1_R3. The third power line M1_R3 may be a path for providing a source voltage (VSS).

The double height cell DHC may be defined between the second power line M1_R2 and the third power line M1_R3. The double height cell DHC may include two first active regions AR1 and two second active regions AR2.

One of the two second active regions AR2 may be adjacent to the second power line M1_R2. The other of the two second active regions AR2 may be adjacent to the third power line M1_R3. The two first active regions AR1 may be adjacent to the first power line M1_R1. When viewed in plan, the first power line M1_R1 may be disposed between the two first active regions AR1.

A second height HE2 may be defined to indicate a length in the first direction D1 of the double height cell DHC. The second height HE2 may be about twice the first height HE1 of FIG. 1. The two first active regions AR1 of the double height cell DHC may be collectively connected to act as one active region.

The double height cell DHC shown in FIG. 2 may be defined as a multi-height cell. In some embodiments, the multi-height cell may include a triple height cell whose cell height is about three times that of the single height cell SHC.

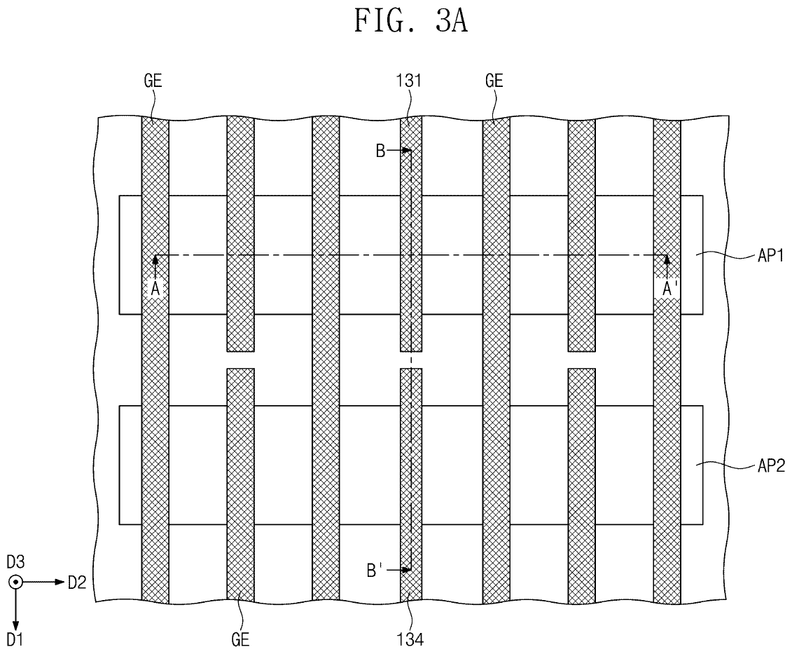

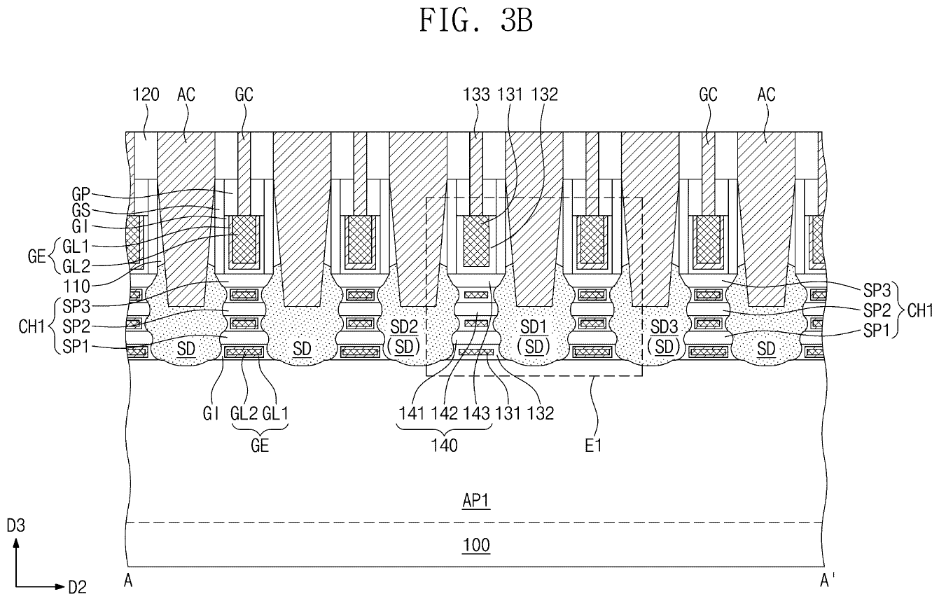

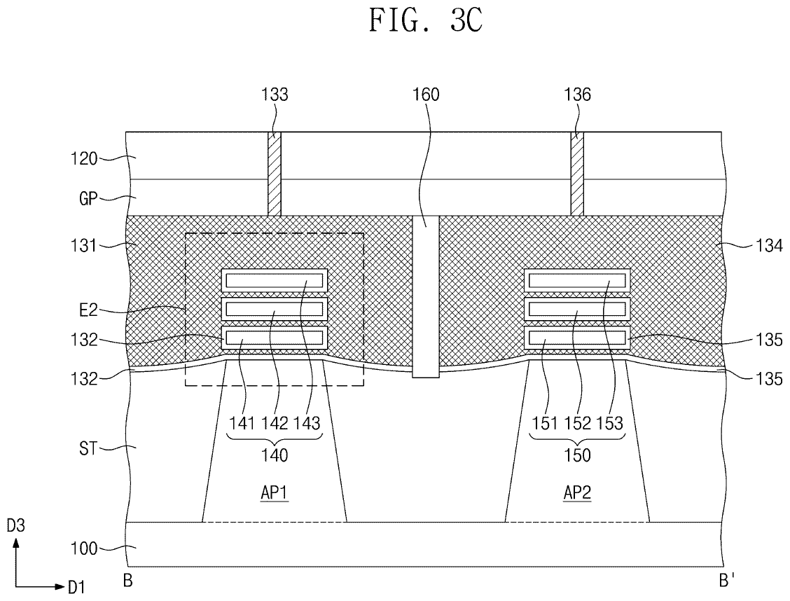

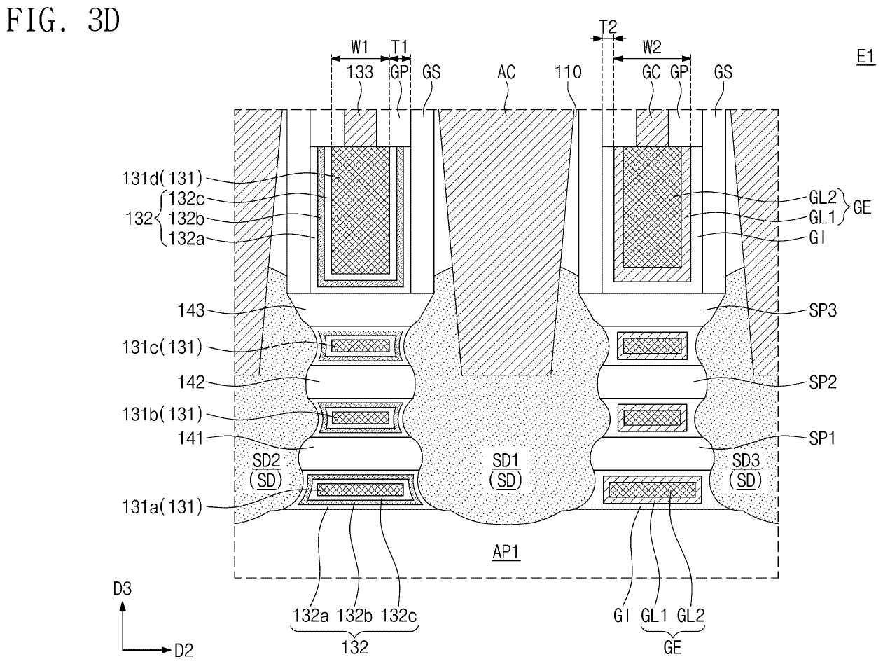

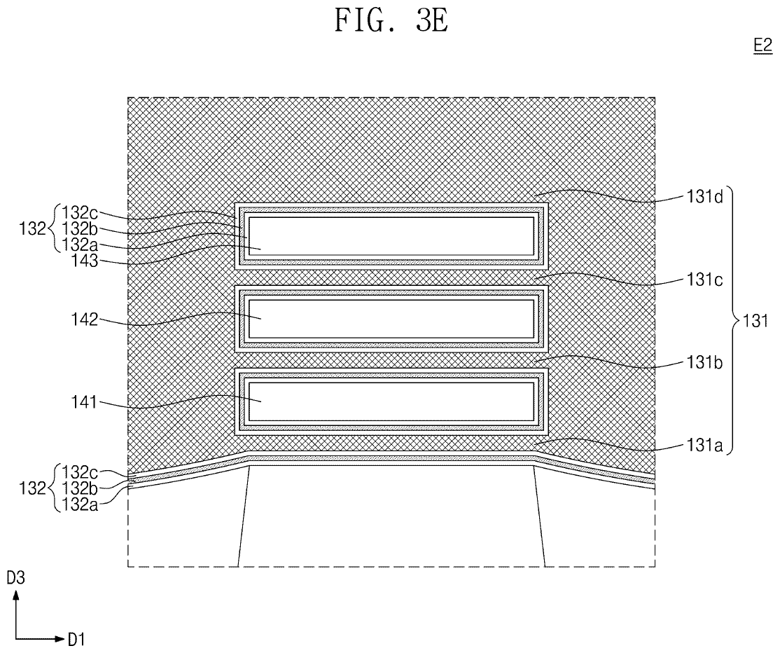

FIG. 3A illustrates a plan view showing a semiconductor device according to some embodiments. FIG. 3B illustrates a cross-sectional view taken along line A-A′ of FIG. 3A. FIG. 3C illustrates a cross-sectional view taken along line B-B′ of FIG. 3A. FIG. 3D illustrates an enlarged view showing section E1 of FIG. 3B. FIG. 3E illustrates an enlarged view showing section E2 of FIG. 3C.

Referring to FIGS. 3A, 3B, and 3C, a semiconductor device may include a substrate 100. The substrate 100 may be a semiconductor substrate, a dielectric substrate, a silicon-on-insulator (SOI) substrate, or a germanium-on-insulator (GOI) substrate. The semiconductor substrate may include, for example, silicon (Si), germanium (Ge), silicon-germanium (SiGe), gallium phosphate (GaP), or gallium arsenide (GaAs). The substrate 100 may have a plate shape that extends along a plane elongated in a first direction D1 and a second direction D2. The first direction D1 and the second direction D2 may intersect each other. For example, the first direction D1 and the second direction D2 may be horizontal directions that are orthogonal to each other.

The substrate 100 may include a first active pattern AP1 and a second active pattern AP2. The first and second active patterns AP1 and AP2 may extend in the second direction D2. The first and second active patterns AP1 and AP2 may be portions of the substrate 100 that protrude in a third direction D3. The third direction D3 may intersect the first direction D1 and the second direction D2. For example, the third direction D3 may be a vertical direction perpendicular to the first direction D1 and the second direction D2.

A device isolation layer ST may be provided on the substrate 100. The device isolation layer ST may be provided therein with the first and second active patterns AP1 and AP2. The device isolation layer ST may include a dielectric material. For example, the device isolation layer ST may include oxide.

Source/drain patterns SD may be provided. The source/drain patterns SD may overlap in the third direction D3 with the first active pattern AP1 or the second active pattern AP2. The source/drain patterns SD, which overlap in the third direction D3 with the first active pattern AP1, may be arranged in the second direction D2 on the first active pattern AP1.

The source/drain patterns SD may be epitaxial patterns formed by a selective epitaxial growth (SEG) process. The source/drain patterns SD may include a semiconductor material. The source/drain patterns SD may include one of silicon (Si), silicon-germanium (SiGe), and germanium (Ge). In some embodiments, the source/drain patterns SD that overlap in the third direction D3 with the first active pattern AP1 may include p-type impurities to have a p-conductivity type.

Channel structures CH1 may be provided. The channel structures CH1 may be provided between the source/drain patterns SD. The channel structures CH1 may overlap in the third direction D3 with the first active pattern AP1 or the second active pattern AP2.

The channel structures CH1 may each include a first semiconductor pattern SP1, a second semiconductor pattern SP2, and a third semiconductor pattern SP3 that overlap in the third direction D3 with each other. The first, second, and third semiconductor patterns SP1, SP2, and SP3 may be spaced apart from each other in the third direction D3. In some embodiments, the first, second, and third semiconductor patterns SP1, SP2, and SP3 may include silicon (Si). For example, each of the first, second, and third semiconductor patterns SP1, SP2, and SP3 may include crystalline silicon. In some embodiments, the first, second, and third semiconductor patterns SP1, SP2, and SP3 may include silicon-germanium (SiGe).

Gate electrodes GE may be provided which extend in the first direction D1. The gate electrode GE may overlap in the third direction D3 with one or more of the first and second active patterns AP1 and AP2. The gate electrode GE may overlap in the third direction D3 with the channel structure CH1. The gate electrode GE and the first, second, and third semiconductor patterns SP1, SP2, and SP3 may constitute a three-dimensional field effect transistor (e.g., MBCFET or GAAFET).

A gate dielectric layer GI may be provided. The gate dielectric layer GI may separate the gate electrode GE from the first, second, and third semiconductor patterns SP1, SP2, and SP3 and the source/drain patterns SD. The gate dielectric layer GI may be in contact with a top surface, a bottom surface, and a sidewall of each of the first, second, and third semiconductor patterns SP1, SP2, and SP3. The gate dielectric layer GI may be in contact with the source/drain patterns SD. The gate dielectric layer GI may include a dielectric material. For example, the gate dielectric layer GI may include oxide.

The gate electrode GE may include a first electrode layer GL1 in contact with the gate dielectric layer GI and a second electrode layer GL2 in contact with the first electrode layer GL1. The first electrode layer GL1 may be provided between the gate dielectric layer GI and the second electrode layer GL2. The first electrode layer GL1 may separate the second electrode layer GL2 from the gate dielectric layer GI.

The first electrode layer GL1 and the second electrode layer GL2 may include different conductive materials from each other. For example, the first electrode layer GL1 may include at least one selected from TIN, TiO, AlN, AlO, TiAlN, and TiAlO, and the second electrode layer GL2 may include at least one selected from Ti and Al.

There may be provided a first blocking channel structure 140 and a second blocking channel structure 150. Each of the first and second blocking channel structures 140 and 150 may be provided between the source/drain patterns SD. Each of the first and second blocking channel structures 140 and 150 may be provided between the gate electrodes GE. Each of the first and second blocking channel structures 140 and 150 may be provided between the channel structures CH1. The first blocking channel structure 140 may overlap in the third direction D3 with the first active pattern AP1. The second blocking channel structure 150 may overlap in the third direction D3 with the second active pattern AP2.

The first blocking channel structure 140 may include a first blocking semiconductor pattern 141, a second blocking semiconductor pattern 142, and a third blocking semiconductor pattern 143 that overlap each other in the third direction D3. The first, second, and third blocking semiconductor patterns 141, 142, and 143 may be spaced apart from each other in the third direction D3. The first, second, and third blocking semiconductor patterns 141, 142, and 143 may include the same material as that of the first, second, and third semiconductor patterns SP1, SP2, and SP3.

The second blocking channel structure 150 may include a fourth blocking semiconductor pattern 151, a fifth blocking semiconductor pattern 152, and a sixth blocking semiconductor pattern 153 that overlap each other in the third direction D3. The fourth, fifth, and sixth blocking semiconductor patterns 151, 152, and 153 may be spaced apart from each other in the third direction D3. The fourth, fifth, and sixth blocking semiconductor patterns 151, 152, and 153 may include the same material as that of the first, second, and third semiconductor patterns SP1, SP2, and SP3.

There may be provided a first blocking electrode 131 and a second blocking electrode 134 that extend in the first direction D1. The first blocking electrode 131 and the second blocking electrode 134 may be arranged in the first direction D1. The first blocking electrode 131 may overlap in the third direction D3 with the first active pattern AP1. The first blocking electrode 131 may overlap in the third direction D3 with the first blocking channel structure 140. The second blocking electrode 134 may overlap in the third direction D3 with the second active pattern AP2. The second blocking electrode 134 may overlap in the third direction D3 with the second blocking channel structure 150. The first blocking electrode 131 and the second blocking electrode 134 may include the same conductive material as that of the second electrode layer GL2 of the gate electrode GE. For example, the first blocking electrode 131 and the second blocking electrode 134 may include at least one selected from Ti and Al.

A blocking electrode separation layer 160 may be provided between the first blocking electrode 131 and the second blocking electrode 134. The blocking electrode separation layer 160 may separate the first blocking electrode 131 and the second blocking electrode 134 from each other in the first direction D1. The blocking electrode separation layer 160 may include a dielectric material.

A first blocking dielectric layer 132 and a second blocking dielectric layer 135 may be provided. The first blocking dielectric layer 132 may separate the first blocking electrode 131 from the first, second, and third blocking semiconductor patterns 141, 142, and 143 and the source/drain patterns SD. The second blocking dielectric layer 135 may separate the second blocking electrode 134 from the fourth, fifth, and fifth blocking semiconductor patterns 151, 152, and 153 and the source/drain patterns SD. The first blocking dielectric layer 132 may be in contact with a top surface, a bottom surface, and a sidewall of each of the first, second, and third blocking semiconductor patterns 141, 142, and 143. The second blocking dielectric layer 135 may be in contact with a top surface, a bottom surface, and a sidewall of each of the fourth, fifth, and sixth blocking semiconductor patterns 151, 152, and 153.

Gate spacers GS may be provided. A pair of gate spacers GS may be disposed on opposite sides of the gate electrode GE, the first blocking electrode 131, or the second blocking electrode 134. The gate spacers GS may extend in the first direction D1. The gate spacers GS may have their top surfaces coplanar with that of a first interlayer dielectric layer 110 which will be discussed below. The gate spacers GS may include a dielectric material.

Gate capping patterns GP may be provided. The gate capping pattern GP may be disposed on the gate electrode GE, the first blocking electrode 131, or the second blocking electrode 134. The gate capping pattern GP may extend in the first direction D1. The gate capping pattern GP may include a dielectric material having an etch selectivity with respect to first and second interlayer dielectric layers 110 and 120 which will be discussed below. For example, the gate capping pattern GP may include nitride.

A first interlayer dielectric layer 110 may be provided to cover the gate spacers GS and the source/drain patterns SD. The first interlayer dielectric layer 110 may have a top surface substantially coplanar with that of the gate capping pattern GP and that of the gate spacer GS. The first interlayer dielectric layer 110 may be provided thereon with a second interlayer dielectric layer 120 that covers the gate capping pattern GP. The first and second interlayer dielectric layers 110 and 120 may include a dielectric material. For example, the first and second interlayer dielectric layers 110 and 120 may include oxide.

Active contacts AC may be provided to penetrate the first and second interlayer dielectric layers 110 and 120. The active contact AC may be electrically connected to the source/drain pattern SD. The gate electrode GE, the first blocking electrode 131, or the second blocking electrode 134 may be provided between the active contacts AC that are adjacent to each other in the second direction D2. The active contact AC may have a bar shape that extends in the first direction D1.

In some embodiments, a metal-semiconductor compound layer may be interposed between the active contact AC and the source/drain pattern SD. In this case, the active contact AC may be electrically connected through the metal-semiconductor compound layer to the source/drain pattern SD. For example, the metal-semiconductor compound layer may include at least one selected from titanium silicide, tantalum silicide, tungsten silicide, nickel silicide, and cobalt silicide.

In some embodiments, the active contact AC may include a conductive pattern and a barrier pattern. The barrier pattern may cover sidewalls and a bottom surface of the conductive pattern. For example, the conductive pattern may include at least one selected from aluminum, copper, tungsten, molybdenum, and cobalt, and the barrier pattern may include at least one selected from titanium, tantalum, tungsten, nickel, cobalt, titanium nitride (TiN), tantalum nitride (TaN), tungsten nitride (WN), nickel nitride (NiN), cobalt nitride (CoN), and platinum nitride (PtN).

A gate contact GC may be provided. The gate contact GC may penetrate the second interlayer dielectric layer 120 and the gate capping pattern GP. The gate contact GC may be in contact with the gate electrode GE. The gate contact GC may include a conductive material.

A first blocking electrode contact 133 may be provided. The first blocking electrode contact 133 may penetrate the second interlayer dielectric layer 120 and the gate capping pattern GP. The first blocking electrode contact 133 may be in contact with the first blocking electrode 131. The first blocking electrode contact 133 may include a conductive material.

A second blocking electrode contact 136 may be provided. The second blocking electrode contact 136 may penetrate the second interlayer dielectric layer 120 and the gate capping pattern GP. The second blocking electrode contact 136 may be in contact with the second blocking electrode 134. The second blocking electrode contact 136 may include a conductive material.

Cells (e.g., single height cells) may be disposed on opposite sides of each of the first blocking electrode 131, the first blocking dielectric layer 132, the first blocking channel structure 140, the second blocking electrode 134, the second blocking dielectric layer 135, and the second blocking channel structure 150. The first blocking electrode 131, the first blocking dielectric layer 132, the first blocking channel structure 140, the second blocking electrode 134, the second blocking dielectric layer 135, and the second blocking channel structure 150 may electrically separate the cells from each other.

Referring to FIGS. 3D and 3E, the source/drain patterns SD that overlap in the third direction D3 with the first active pattern AP1 may include a first source/drain pattern SD1, a second source/drain pattern SD2 adjacent to the first source/drain pattern SD1, and a third source/drain pattern SD3 adjacent to the first source/drain pattern SD1. The first source/drain pattern SD1 may be provided between the second and third source/drain patterns SD2 and SD3.

The first blocking electrode 131 and the first blocking dielectric layer 132 may be provided between the first and second source/drain patterns SD1 and SD2. The gate electrode GE and the gate dielectric layer GI may be provided between the first and third source/drain patterns SD1 and SD3.

The first blocking electrode 131 may include a first blocking electrode part 131a between the first active pattern AP1 and the first blocking semiconductor pattern 141, a second blocking electrode part 131b between the first and second blocking semiconductor patterns 141 and 142, a third blocking electrode part 131c between the second and third blocking semiconductor patterns 142 and 143, and a fourth blocking electrode part 131d on the first, second, and third blocking semiconductor patterns 141, 142, and 143.

The first blocking dielectric layer 132 may include a first layer 132a, a second layer 132b, and a third layer 132c. The first layer 132a may be in contact with the first active pattern AP1, the first to third blocking semiconductor patterns 141 to 143, the source/drain patterns SD, and the gate spacers GS. The third layer 132c may be in contact with the first blocking electrode 131. The second layer 132b may be provided between the first layer 132a and the third layer 132c. The second layer 132b may separate the first layer 132a and the third layer 132c from each other.

The first blocking dielectric layer 132 may include a different dielectric material from that of the gate dielectric layer GI. The second layer 132b may include a different dielectric material from that of the first layer 132a and that of the third layer 132c. For example, the second layer 132b may include nitride (e.g., SiN), and the first layer 132a and the third layer 132c may include oxide (e.g., SiO or HfO).

The first blocking dielectric layer 132 may include a part disposed between the first active pattern AP1 and the first blocking semiconductor pattern 141, a part disposed between the first and second blocking semiconductor patterns 141 and 142, a part disposed between the second and third blocking semiconductor patterns 142 and 143, and a part disposed on the first, second, and third blocking semiconductor patterns 141, 142, and 143. The part of the first blocking dielectric layer 132 disposed on the first, second, and third blocking semiconductor patterns 141, 142, and 143 may have a U shape when viewed in cross-section as shown in FIG. 3D.

Each of the first, second, and third layers 132a, 132b, and 132c may include a part disposed between the first active pattern AP1 and the first blocking semiconductor pattern 141, a part disposed between the first and second blocking semiconductor patterns 141 and 142, a part disposed between the second and third blocking semiconductor patterns 142 and 143, and a part disposed on the first, second, and third blocking semiconductor patterns 141, 142, and 143. The part of each of the first, second, and third layers 132a, 132b, and 132c that is disposed on the first, second, and third blocking semiconductor patterns 141, 142, and 143 may have a U shape when viewed in cross-section as shown in FIG. 3D.

A width of the first blocking electrode 131 may be less than that of the gate electrode GE. For example, a width W1 in the second direction D2 of the fourth blocking electrode part 131d of the first blocking electrode 131 may be less than a width W2 in the second direction D2 of a part of the gate electrode GE disposed on the semiconductor patterns SP1, SP2, and SP3.

A thickness of the first blocking dielectric layer 132 may be greater than that of the gate dielectric layer GI. For example, a thickness T1 in the second direction D2 of a part of the first blocking dielectric layer 132 in contact with a sidewall of the fourth blocking electrode part 131d of the first blocking electrode 131 may be greater than a thickness T2 in the second direction D2 of a part of the gate dielectric layer GI in contact with a sidewall of a part of the gate electrode GE on the semiconductor patterns SP1, SP2, and SP3.

The second layer 132b of the first blocking dielectric layer 132 may include a material in which electrons or holes are trapped. When a voltage is applied to the first blocking electrode 131, electrons or holes may be trapped in the second layer 132b of the first blocking dielectric layer 132. The holes or electrons trapped in the second layer 132b of the first blocking dielectric layer 132 may increase a threshold voltage of the first, second, and third blocking semiconductor patterns 141, 142, and 143, and the first, second, and third blocking semiconductor patterns 141, 142, and 143 may be electrically blocked. Therefore, the first blocking electrode 131, the first blocking dielectric layer 132, and the first, second, and third blocking semiconductor patterns 141, 142, and 143 may electrically separate from each other cells on opposite sides thereof.

In some embodiments, the first, second, and third source/drain patterns SD1, SD2, and SD3 may include p-type impurities, a negative voltage may be applied to the first blocking electrode 131 to cause holes to be trapped in the second layer 132b of the first blocking dielectric layer 132, and the trapped holes may increase a threshold voltage of the first, second, and third blocking semiconductor patterns 141, 142, and 143.

In some embodiments, the first, second, and third source/drain patterns SD1, SD2, and SD3 may include n-type impurities, a positive voltage may be applied to the first blocking electrode 131 to cause electrons to be trapped in the second layer 132b of the first blocking dielectric layer 132, and the trapped electrons may increase a threshold voltage of the first, second, and third blocking semiconductor patterns 141, 142, and 143.

Referring to FIGS. 3A, 3B, and 3C, the second blocking electrode 134, the second blocking dielectric layer 135, and the fourth, fifth, and sixth blocking semiconductor patterns 151, 152, and 153 may have their structures and operations similar to those of the first blocking electrode 131, the first blocking dielectric layer 132, and the first, second, and third blocking semiconductor patterns 141, 142, and 143.

In some embodiments, the first active pattern AP1 may be included in a PMOSFET region, and the second active pattern AP2 may be included in an NMOSFET region. In this case, a negative voltage may be applied to the first blocking electrode 131 to electrically block the first, second, and third blocking semiconductor patterns 141, 142, and 143, and a positive voltage may be applied to the second blocking electrode 134 to electrically block the fourth, fifth, and sixth blocking semiconductor patterns 151, 152, and 153.

In a semiconductor device according to some embodiments, holes or electrons may be trapped to electrically insulate a cell including the first source/drain pattern SD1 and a cell including the second source/drain pattern SD2.

In addition, it may be possible to omit a process for forming a physical insulation structure that physically insulates the cell including the first source/drain pattern SD1 and the cell including the second source/drain pattern SD2. For example, a deposition material for forming the physical insulation structure may remain on the source/drain pattern SD to limit and/or prevent an increase in difficulty in forming the active contact AC.

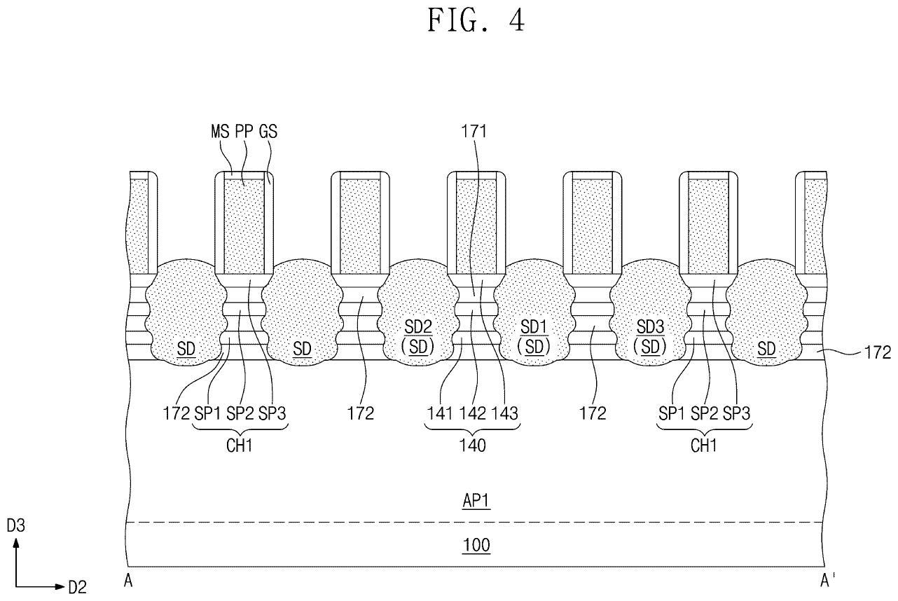

FIGS. 4, 5, 6, 7, and 8 illustrate cross-sectional views showing a method of fabricating a semiconductor device depicted in FIGS. 3A to 3E.

Referring to FIG. 4, a first active pattern AP1 and a second active pattern (see AP2 of FIG. 3C) may be formed on a substrate 100. A device isolation layer (see ST of FIG. 3C) may be formed. The channel structures CH1, a first blocking channel structure 140, and a second blocking channel structure (see 150 of FIG. 3C) may be formed.

The formation of the channel structures CH1, the first blocking channel structure 140, and the second blocking channel structure 150 may include forming first preliminary layers and second preliminary layers that are alternately stacked on each other, forming sacrificial patterns PP, mask patterns MS, and gate spacers GS, and using the mask patterns MS and the gate spacers GS as an etching mask to etch the first preliminary layers and the second preliminary layers.

The first preliminary layer may include a material having an etch selectivity with respect to the second preliminary layer. For example, the second preliminary layer may include Si, and the first preliminary layer may include SiGe. The sacrificial pattern PP may include, for example, polysilicon. The mask pattern MS may include a dielectric material.

The second preliminary layers may be etched to form semiconductor patterns SP1, SP2, and SP3 and blocking semiconductor patterns 141, 142, 143, 151, 152, and 153. The first preliminary layers may be etched to form first sacrificial semiconductor patterns 171 and second sacrificial semiconductor patterns 172. The first sacrificial semiconductor patterns 171 and the second sacrificial semiconductor patterns 172 may include a material having an etch selectivity with respect to the semiconductor patterns SP1, SP2, and SP3 and the blocking semiconductor patterns 141, 142, 143, 151, 152, and 153.

Source/drain patterns SD may be formed. The source/drain patterns SD may be formed by a selective epitaxial growth process. The first sacrificial semiconductor patterns 171 may be disposed between first and second source/drain patterns SD1 and SD2.

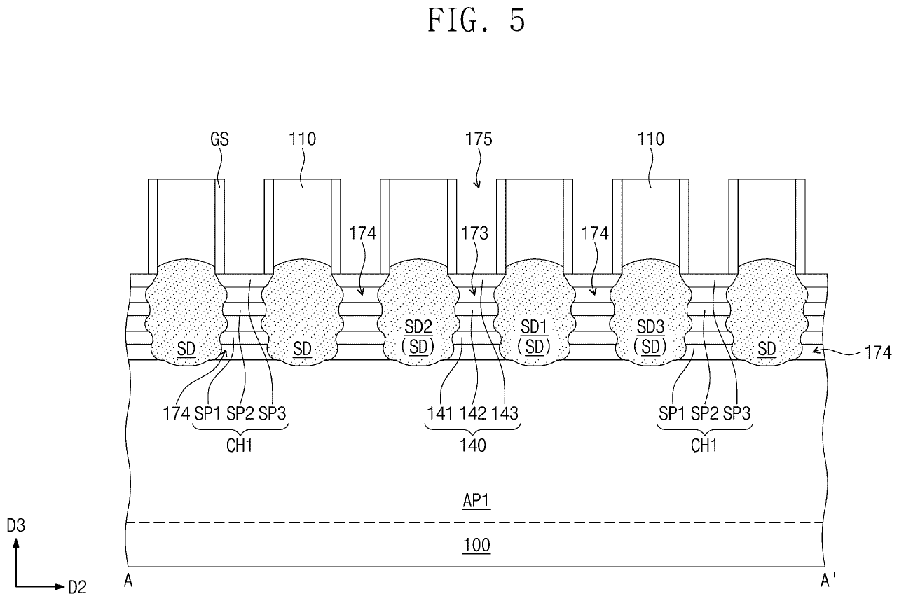

Referring to FIG. 5, a first interlayer dielectric layer 110 may be formed. The mask patterns MS and the sacrificial patterns PP may be removed. First spaces 175 may be defined to indicate empty spaces formed when the sacrificial patterns PP are removed. The first sacrificial semiconductor patterns 171 and the second sacrificial semiconductor patterns 172 may be removed through the first spaces 175. Second spaces 173 may be defined to indicate empty spaces formed when the first sacrificial semiconductor patterns 171 are removed. Third spaces 174 may be defined to indicate empty spaces formed when the second sacrificial semiconductor patterns 172 are removed.

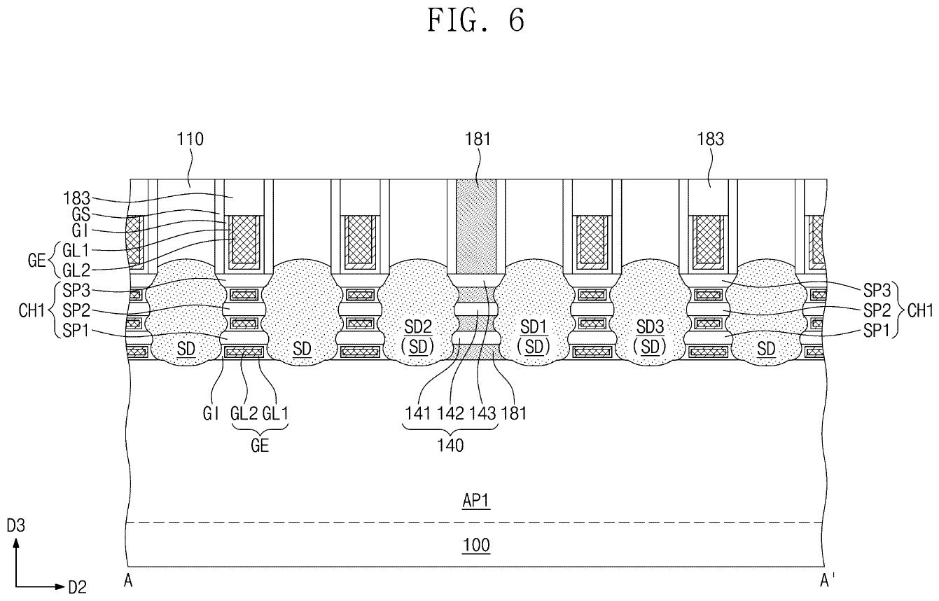

Referring to FIG. 6, a filling layer 181 may be formed to fill the second spaces 173 and the first space 175 that overlaps in a third direction D3 with the second spaces 173. The filling layer 181 may include, for example, metal or nitride.

Gate dielectric layers GI, gate electrodes GE, and preliminary capping layers 183 may be formed to fill the third spaces 174 and the first spaces 175 that overlap in the third direction D3 with the third spaces 174. The preliminary capping layers 183 may include, for example, nitride.

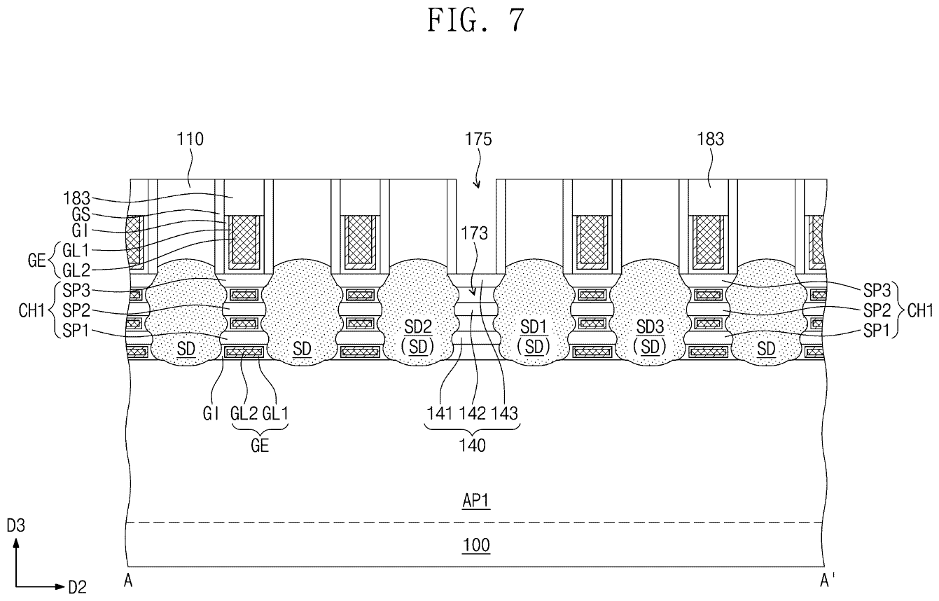

Referring to FIG. 7, the filling layer 181 may be removed. The removal of the filling layer 181 may open the second spaces 173 and the first space 175 that overlaps in the third direction D3 with the second spaces 173.

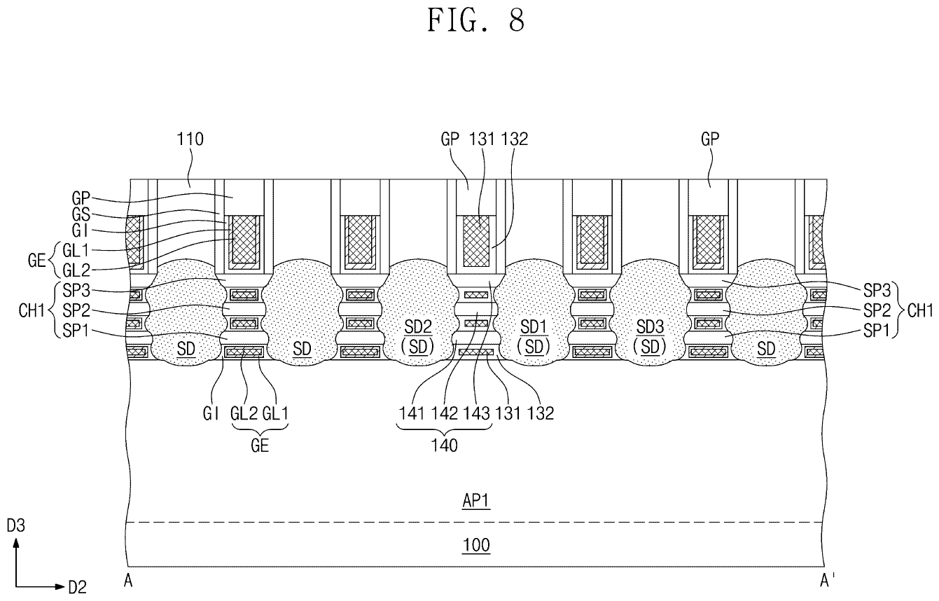

Referring to FIG. 8, a first blocking electrode 131, a first blocking dielectric layer 132, a second blocking electrode (see 134 of FIG. 3C), and a second blocking dielectric layer (see 135 of FIG. 3C) may be formed to fill the second spaces 173 and the first space 175 that overlaps in the third direction D3 with the second spaces 173. A blocking electrode separation layer 160 may be formed between the first blocking electrode 131 and the second blocking electrode 134 and between the first blocking dielectric layer 132 and the second blocking dielectric layer 135 (see 160 in FIG. 3C).

The preliminary capping layers 183 may be removed. Gate capping patterns GP may be formed on the gate electrodes GE, the first blocking electrode 131, and the second blocking electrode 134.

Referring to FIGS. 3B and 3C, a second interlayer dielectric layer 120 may be formed. Active contacts AC, gate contacts GC, a first blocking electrode contact 133, and a second blocking electrode contact 136 may be formed.

In some embodiments, in a process to remove the second sacrificial semiconductor patterns 172 and the sacrificial patterns PP, the first sacrificial semiconductor patterns 171 may not be removed, and the sacrificial pattern PP overlapping in the third direction D3 with the first sacrificial semiconductor patterns 171 may also not be removed. A mask layer may be formed to cover the first sacrificial semiconductor patterns 171 and the sacrificial pattern PP that overlaps in the third direction D3 with the first sacrificial semiconductor patterns 171, and there may thus be no removal of the first sacrificial semiconductor patterns 171 and the sacrificial pattern PP that overlaps in the third direction D3 with the first sacrificial semiconductor patterns 171. After the formation of the gate dielectric layers GI and the gate electrode GE, there may be removal of the first sacrificial semiconductor patterns 171 and the sacrificial pattern PP that overlaps in the third direction D3 with the first sacrificial semiconductor patterns 171.

In some embodiments, instead of forming the preliminary capping layers 183, the gate capping patterns GP may be formed on the gate electrodes GE. After that, after the formation of the blocking electrodes 131 and 134 and the blocking dielectric layers 132 and 135, the gate capping pattern GP may be formed on the blocking electrodes 131 and 134.

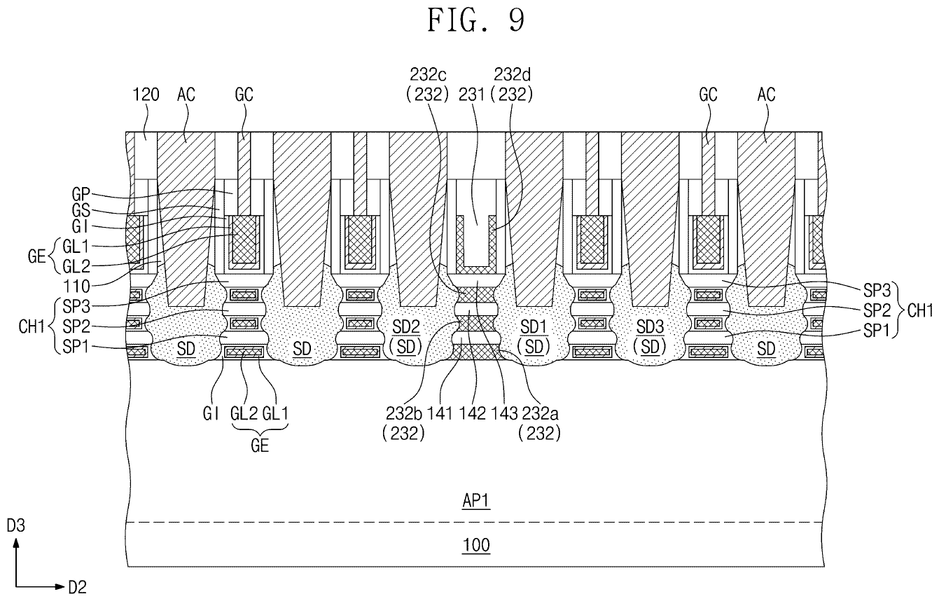

FIG. 9 illustrates a cross-sectional view showing a semiconductor device according to some embodiments. Except that discussed above, a semiconductor device of FIG. 9 may be similar to the semiconductor device of FIGS. 3A to 3E.

Referring to FIG. 9, a semiconductor device may include a first material layer 232 between the first and second source/drain patterns SD1 and SD2. The first material layer 232 may include a first part 232a between the first blocking semiconductor pattern 141 and the first active pattern AP1, a second part 232b between the first and second blocking semiconductor patterns 141 and 142, a third part 232c between the second and third blocking semiconductor patterns 142 and 143, and a fourth part 232d on the first, second, and third blocking semiconductor patterns 141, 142, and 143. When viewed in cross-section as shown in FIG. 9, the fourth part 232d of the first material layer 232 may have a U shape. The first material layer 232 may be electrically floated. The first material layer 232 may not be provided with a contact electrically connected thereto.

A capping dielectric layer 231 may be provided on the fourth part 232d of the first material layer 232. A lower portion of the capping dielectric layer 231 may be provided in the fourth part 232d of the first material layer 232. An upper portion of the capping dielectric layer 231 may be located at a higher level than that of the fourth part 232d of the first material layer 232. A width of the lower portion of the capping dielectric layer 231 may be less than that of the upper portion of the capping dielectric layer 231. The capping dielectric layer 231 may include a dielectric material. For example, the capping dielectric layer 231 may include nitride.

The first material layer 232 may have a work function different from that of the gate electrode GE. As the first material layer 232 and the gate electrode GE are different from each other in terms of work function, the first, second, and third blocking semiconductor patterns 141, 142, and 143 may have an increased threshold voltage and may be electrically blocked.

In some embodiments, the first active pattern AP1 may be included in a PMOSFET region, and the first material layer 232 may have a work function less than that of the gate electrode GE. In this case, for example, the gate electrode GE may include Ti or Al, and the first material may include at least one selected from Ca, K, Lu, Eu, Gd, La, Mg, As, Ba, Ce, Cs, Hf, Li, Nd, Rb, Tb, Yb, Na, Sr, Tl, Sc, Sm, Th, U, Y, and Zr.

In some embodiments, the first active pattern AP1 may be included in an NMOSFET region, and the first material layer 232 may have a work function greater than that of the gate electrode GE. In this case, for example, the gate electrode GE may include Ti or Al, and the first material layer 232 may include at least one selected from Au, Be, Co, Cu, Hg, Fe, Ir, Cr, Mo, Ru, Se, Sn, Ni, Pd, Re, Sb, Si, Te, Os, Pt, and Rh.

In some embodiments, a semiconductor device may include the first active pattern AP1 included in a PMOSFET region and the second active pattern AP2 included in an NMOSFET region. The first material layer 232 on the first active pattern AP1 may have a work function less than that of the gate electrode GE. A second material layer may be provided on the second active pattern AP2. The second material layer may include a material different from that of the first material layer 232. The second material layer may have a work function greater than that of the gate electrode GE.

In a semiconductor device according to some embodiments of inventive concepts, cells may be electrically separated through an electrical insulation structure.

In a semiconductor device according to some embodiments of inventive concepts, a process for forming a structure that physically insulates cells may be omitted, and thus difficulty of subsequent process may be limited and/or prevented from being increased due to a process for forming the physical insulation structure.

Although some embodiments of inventive concepts have been discussed with reference to accompanying figures, it will be understood that various changes in form and details may be made therein without departing from the spirit and scope of inventive concepts. It therefore will be understood that the embodiments described above are just illustrative but not limitative in all aspects.

What is claimed is:

1. A semiconductor device, comprising:
a first source/drain pattern;
a second source/drain pattern and a third source/drain pattern adjacent to the first source/drain pattern;
a plurality of semiconductor patterns between the first source/drain pattern and the third source/drain pattern;
a gate dielectric layer in contact with the plurality of semiconductor patterns;
a gate electrode in contact with the gate dielectric layer;
a plurality of blocking semiconductor patterns between the first source/drain pattern and the second source/drain pattern;
a blocking dielectric layer in contact with the plurality of blocking semiconductor patterns; and
a blocking electrode in contact with the blocking dielectric layer,
wherein the blocking dielectric layer includes a first layer in contact with the first source/drain pattern and the second source/drain pattern, a second layer in contact with the blocking electrode, and a third layer between the first layer and the second layer, and
wherein a dielectric material in the third layer is different from a dielectric material of the first layer and a dielectric material of the second layer.

2. The semiconductor device of claim 1, wherein
the first layer and the second layer include oxide, and
the third layer includes nitride.

3. The semiconductor device of claim 1, wherein a thickness of the blocking dielectric layer is greater than a thickness of the gate dielectric layer.

4. The semiconductor device of claim 1, wherein the blocking electrode includes:
a first blocking electrode part over the plurality of blocking semiconductor patterns; and
a second blocking electrode part between the plurality of blocking semiconductor patterns.

5. The semiconductor device of claim 4, wherein a width of the first blocking electrode part is less than a width of a part of the gate electrode over the plurality of semiconductor patterns.

6. The semiconductor device of claim 1, further comprising:
a blocking electrode contact in contact with the blocking electrode.

7. The semiconductor device of claim 1, wherein the gate electrode includes:
a first electrode layer in contact with the gate dielectric layer; and
a second electrode layer in contact with the first electrode layer.

8. The semiconductor device of claim 7, wherein a conductive material in the second electrode layer is the same as a conductive material of the blocking electrode.

9. A semiconductor device, comprising:
a first source/drain pattern;
a second source/drain pattern and a third source/drain pattern adjacent to the first source/drain pattern;
a plurality of semiconductor patterns between the first source/drain pattern and the third source/drain pattern;
a gate dielectric layer in contact with the plurality of semiconductor patterns;
a gate electrode in contact with the gate dielectric layer;
a plurality of blocking semiconductor patterns between the first source/drain pattern and the second source/drain pattern;
a blocking dielectric layer in contact with the plurality of blocking semiconductor patterns; and
a first blocking electrode in contact with the blocking dielectric layer,
wherein a dielectric material in the blocking dielectric layer is different from a dielectric material of the gate dielectric layer.

10. The semiconductor device of claim 9, wherein the blocking dielectric layer includes:
a first layer in contact with the first source/drain pattern and the second source/drain pattern;
a second layer in contact with the first blocking electrode; and
a third layer between the first layer and the second layer,
wherein a dielectric material in the third layer includes is different from a dielectric material of the first layer, a dielectric material of the second layer, and the dielectric material of the gate dielectric layer.

11. The semiconductor device of claim 9, wherein the blocking dielectric layer is in contact with top surfaces of the plurality of blocking semiconductor patterns and bottom surfaces of the plurality of blocking semiconductor patterns.

12. The semiconductor device of claim 9, further comprising:
a plurality of gate spacers overlapping the plurality blocking semiconductor patterns,
wherein the blocking dielectric layer is in contact with the plurality of gate spacers.

13. The semiconductor device of claim 12, further comprising:
a gate capping pattern between the plurality of gate spacers,
wherein the gate capping pattern is in contact with the blocking dielectric layer and the first blocking electrode.

14. The semiconductor device of claim 9, further comprising:
a first active pattern overlapping the first blocking electrode;
a second active pattern spaced apart from the first active pattern;
a second blocking electrode overlapping the second active pattern; and
a blocking electrode separation layer between the first blocking electrode and the second blocking electrode.

15. The semiconductor device of claim 14, wherein
a negative voltage is applied to the first blocking electrode, and
a positive voltage is applied to the second blocking electrode.

16. The semiconductor device of claim 15, wherein the first, second, and third source/drain patterns include p-type impurities.

17. The semiconductor device of claim 9, wherein
a first part of the blocking dielectric layer is over the plurality of blocking semiconductor patterns, and
a second part of the blocking dielectric layer is between the plurality of blocking semiconductor patterns.

18. The semiconductor device of claim 17, wherein the first part of the blocking dielectric layer has a U shape.

19. A semiconductor device, comprising:
a first source/drain pattern;
a second source/drain pattern and a third source/drain pattern adjacent to the first source/drain pattern;
a plurality of semiconductor patterns between the first source/drain pattern and the third source/drain pattern;
a gate dielectric layer in contact with the plurality of semiconductor patterns;
a gate electrode in contact with the gate dielectric layer;
a gate electrode contact electrically connected to the gate electrode;
a plurality of blocking semiconductor patterns between the first source/drain pattern and the second source/drain pattern;
a blocking dielectric layer in contact with the blocking semiconductor patterns;
a blocking electrode in contact with the blocking dielectric layer;
a blocking electrode contact electrically connected to the blocking electrode;
a plurality of gate spacers in contact with the blocking dielectric layer;
a gate capping pattern in contact with the blocking dielectric layer and a top surface of the blocking electrode; and
an active contact electrically connected to a corresponding one of the first source/drain pattern, the second source/drain pattern, and the third source/drain pattern, wherein
the blocking dielectric layer includes a first layer, a second layer, and a third layer,
the first layer is in contact with the first source/drain pattern, the second source/drain pattern, and the plurality of blocking semiconductor patterns,
the second layer is in contact with the blocking electrode,
the third layer is between the first layer and the second layer,
the first layer and the second layer include oxide, and
the third layer includes nitride.

20. The semiconductor device of claim 19, wherein
the first layer, the second layer, and the third layer are in contact with the gate capping pattern, and
the first layer is in contact with the plurality of gate spacers.
